(19) United States
(12) Patent Application Publication
(10) Pub. No.: US 2026/0157196 A1
(43) Pub. Date: Jun. 4, 2026

(54) POWER MODULE

(71) Applicant: SHINKO ELECTRIC INDUSTRIES CO., LTD., Nagano (JP)

(72) Inventor: Koji BANDO, Nagano (JP)

(21) Appl. No.: 19/403,597

(22) Filed: Nov. 28, 2025

(30) Foreign Application Priority Data
Dec. 3, 2024 (JP) 2024-209874

(51) Int. Cl. H10W 70/60; H05K 1/11; H05K 1/181; H10D 80/20; H10W 44/00; H10W 70/40; H10W 70/652; H10W 90/00; H10W 90/10; H10W 90/26

(52) U.S. Cl. CPC H10W 70/611; H05K 1/115; H05K 1/181; H10D 80/251; H10W 44/501; H10W 70/427; H10W 70/481; H10W 70/652; H10W 90/10; H10W 90/26; H10W 90/736; H10W 90/791; H05K 2201/042; H05K 2201/049; H05K 2201/10166

(57) ABSTRACT

A power module includes a first device having first and second electrodes on opposite surfaces, a second device having third and fourth electrodes on opposite surfaces, first and second insulators bonded with the first and second devices, respectively, a first conductor stacked on and penetrating the first insulator and coupled to the first electrode, a second conductor coupled to the second electrode, a third conductor stacked on and penetrating the second insulator and coupled to the third electrode, a fourth conductor coupled to the fourth electrode, a fifth conductor coupling the first and fourth conductors, an insulating film facing the first and second conductors and facing the third and fourth conductors at opposite surfaces thereof, and first and second conductive layers provided on opposite surfaces of the insulating film and coupled to the second and third conductors, respectively. The first and second conductive layers overlap in a plan view.

### CROSS-REFERENCE TO RELATED APPLICATIONS

This application is based upon and claims priority to Japanese Patent Application No. 2024-209874, filed on Dec. 3, 2024, the entire contents of which are incorporated herein by reference.

### FIELD

Certain aspects of the embodiments discussed herein are related to power modules.

### BACKGROUND

There is a proposed power module having two semiconductor devices overlapping each other in a plan view.

Related art include International Publication Pamphlet No. WO 2024/202838, Japanese Laid-Open Patent Publication No. 2014-045010, and Japanese Laid-Open Patent Publication No. 2010-129801, for example.

In recent years, there are increased demands to further reduce an inductance of the power module.

### SUMMARY

Accordingly, it is an object in one aspect of the embodiments of the present disclosure to provide a power module capable of reducing an inductance.

According to an aspect of the embodiments of the present disclosure, a power module includes a first semiconductor device having a first surface, a second surface opposite to the first surface, a first electrode provided on the first surface, and a second electrode provided on the second surface; a second semiconductor device having a third surface, a fourth surface opposite to the third surface, a third electrode provided on the third surface, and a fourth electrode provided on the fourth surface; a first insulating base material having a fifth surface bonded with the first semiconductor device, and a sixth surface opposite to the fifth surface; a second insulating base material having a seventh surface bonded with the second semiconductor device, and an eighth surface opposite to the seventh surface; a first conductive member penetrating the first insulating base material, electrically connected to the first electrode, and stacked on the sixth surface of the first insulating base material; a second conductive member electrically connected to the second electrode; a third conductive member penetrating the second insulating base material, electrically connected to the third electrode, and stacked on the eighth surface of the second insulating base material; a fourth conductive member electrically connected to the fourth electrode; a fifth conductive member electrically connecting the first conductive member and the fourth conductive member; an insulating film having a ninth surface facing the first conductive member and the second conductive member, and a tenth surface facing the third conductive member and the fourth conductive member; a first conductive layer provided on the ninth surface and electrically connected to the second conductive member; and a second conductive layer provided on the tenth surface and electrically connected to the third conductive member, wherein the first conductive layer and the second conductive layer overlap in a plan view.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a perspective view (part 1) illustrating a power module according to an embodiment;

FIG. 2 is a perspective view (part 2) illustrating the power module according to the embodiment;

FIG. 3 is a perspective view (part 1) illustrating a part of the power module according to the embodiment;

FIG. 4 is a perspective view (part 2) illustrating a part of the power module according to the embodiment;

FIG. 5 is a perspective view (part 3) illustrating a part of the power module according to the embodiment;

FIG. 6 is a perspective view (part 4) illustrating a part of the power module according to the embodiment;

FIG. 7 is a perspective view (part 5) illustrating a part of the power module according to the embodiment;

FIG. 8 is a perspective view (part 6) illustrating a part of the power module according to the embodiment;

FIG. 9 is a perspective view (part 7) illustrating a part of the power module according to the embodiment;

FIG. 10 is a perspective view (part 8) illustrating a part of the power module according to the embodiment;

FIG. 11 is a cross sectional view schematically illustrating the power module according to the embodiment;

FIG. 12 is a cross sectional view schematically illustrating a part of the power module according to the embodiment;

FIG. 13 is a top view schematically illustrating a part of the power module according to the embodiment;

FIG. 14 is a bottom view schematically illustrating a part of the power module according to the embodiment; and

FIG. 15 is a circuit diagram illustrating the power module according to the embodiment.

### DESCRIPTION OF EMBODIMENTS

Hereinafter, embodiments will be described in detail with reference to the accompanying drawings. In the present specification and the drawings, constituent elements having substantially the same functional configuration are designated by the same reference numerals, and a redundant description thereof may be omitted. Further, in the present disclosure, an X-axis (X1-X2 direction), a Y-axis (Y1-Y2 direction), and a Z-axis (Z1-Z2 direction) are mutually orthogonal directions. A plane including the X-axis and the Y-axis is referred to as an XY-plane, a plane including the Y-axis and the Z-axis is referred to as a YZ-plane, and a plane including the Z-axis and the X-axis is referred to as a ZX-plane. For the sake of convenience, the Z1-Z2 direction is defined as a vertical direction (or up-down direction), a Z1-side is defined as an upper side, and a Z2-side is defined as a lower side. Moreover, a plan view refers to a view of an object viewed from the Z1-side, and a planar shape refers to a shape of the object in the plan view viewed from the Z1-side. However, the power module may be used in an upside-down state or may be disposed at an arbitrary angle.

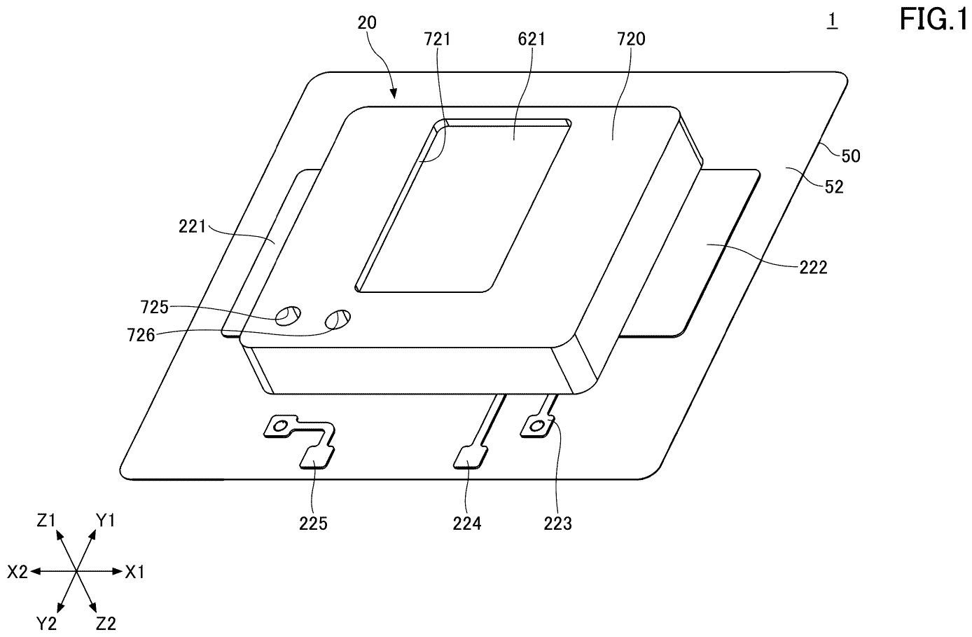

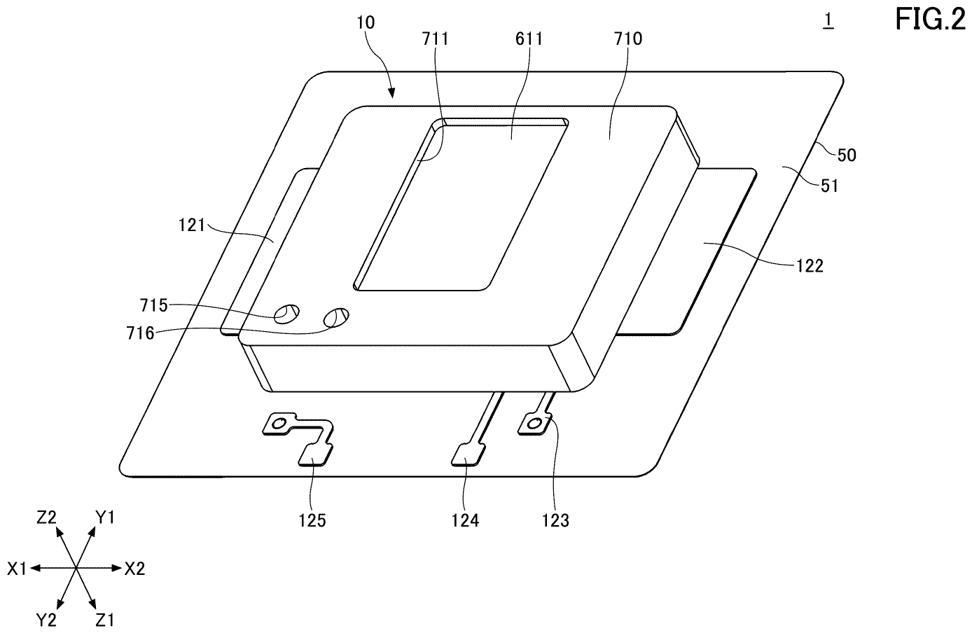

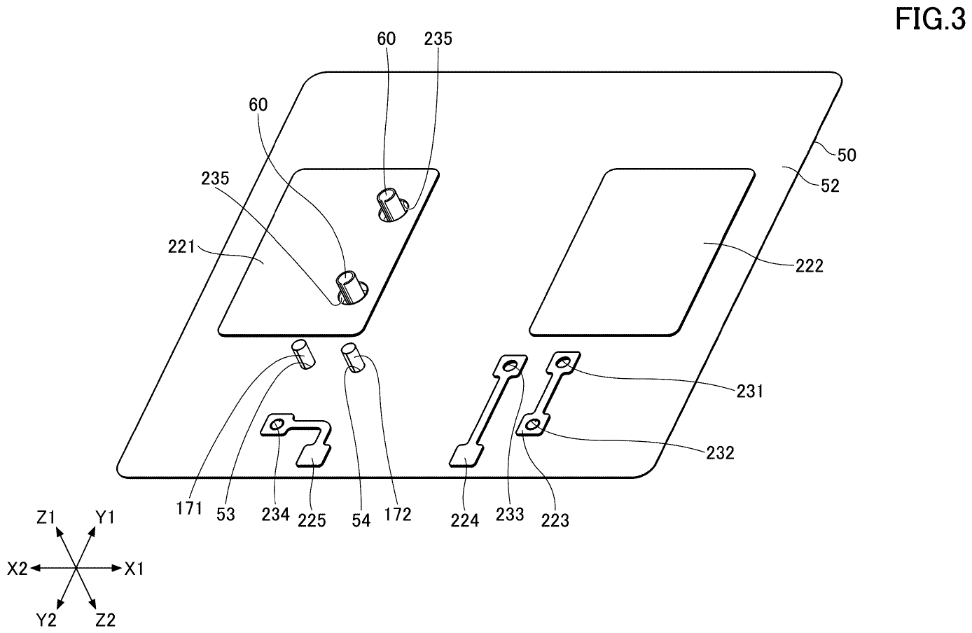

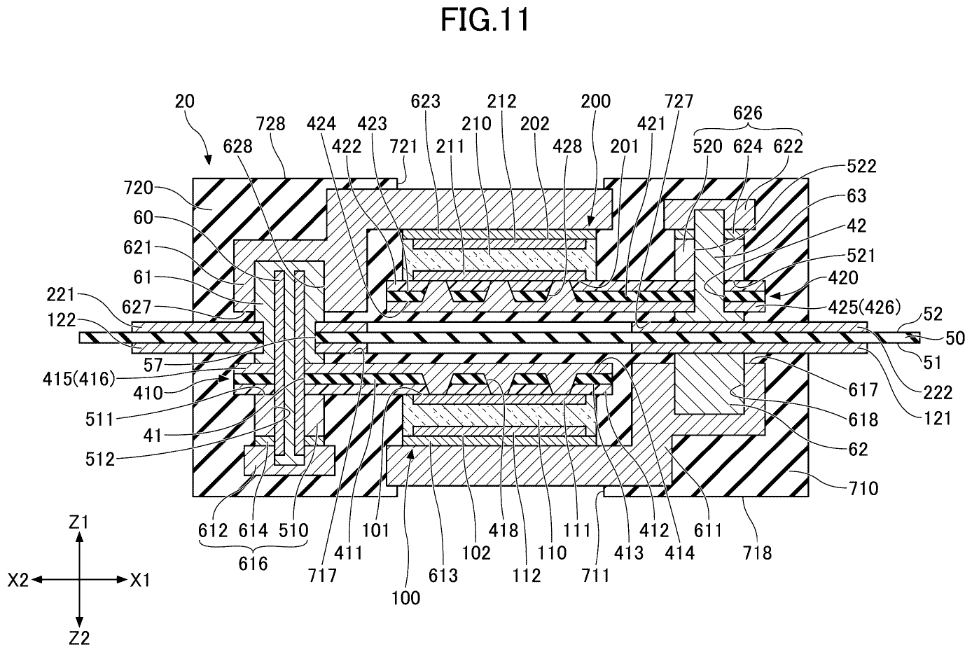

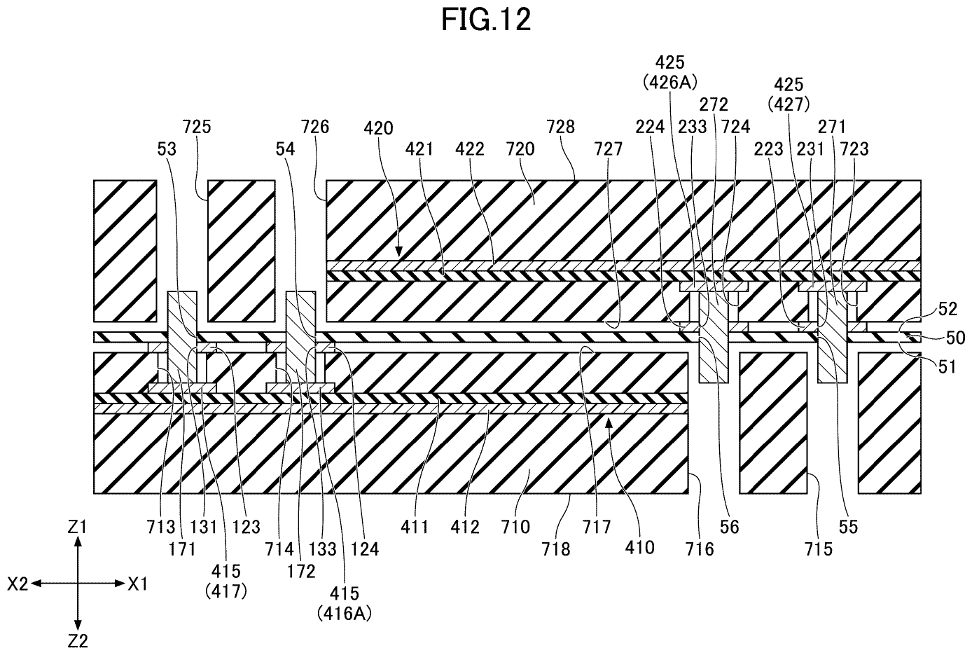

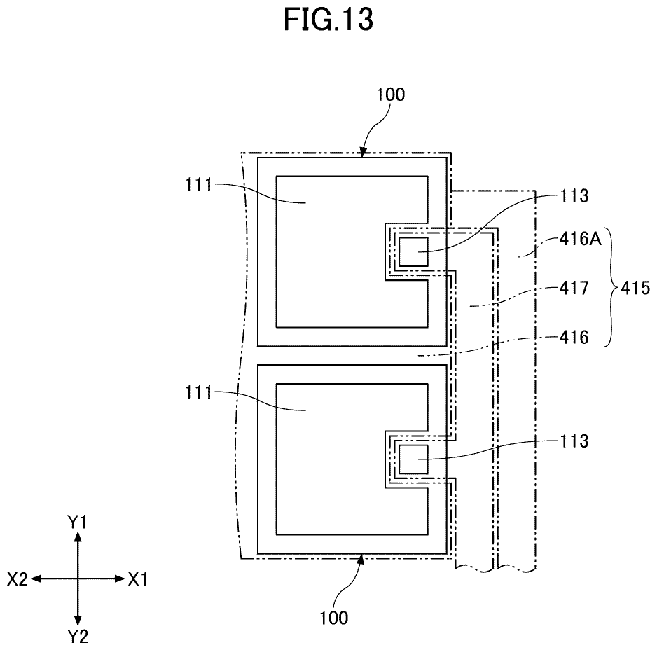

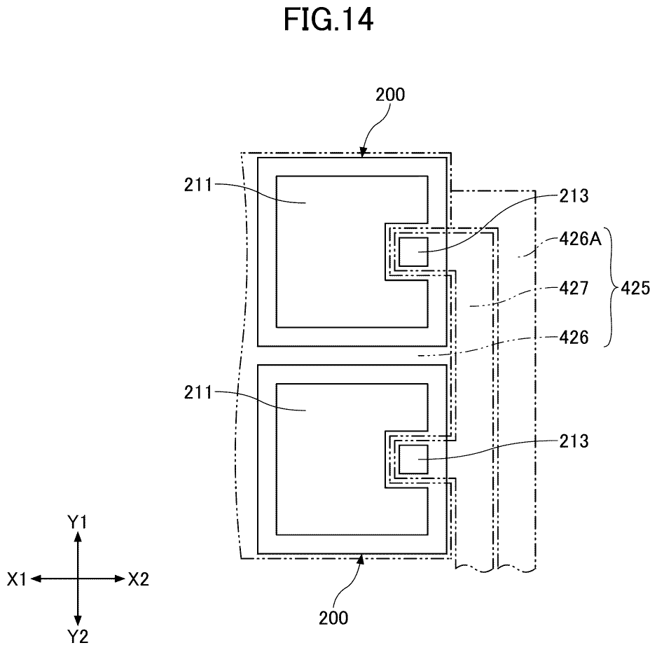

Embodiments of the present disclosure will be described. The embodiments relate to a power module. FIG. 1 and FIG. 2 are perspective views illustrating the power module according to an embodiment. FIG. 3 through FIG. 10 are perspective views illustrating parts of the power module according to the embodiment. FIG. 11 is a cross sectional view schematically illustrating the power module according to the embodiment. FIG. 12 is a cross sectional view schematically illustrating a part of the power module according to the embodiment. FIG. 13 is a top view schematically illustrating a part of the power module according to the embodiment. FIG. 14 is a bottom view schematically illustrating a part of the power module according to the embodiment.

As illustrated in FIG. 1 through FIG. 14, a power module 1 according to the embodiment includes a semiconductor package 10, a semiconductor package 20, an insulating film 50, and conductive pins 60.

The insulating film 50 is provided between the semiconductor package 10 and the semiconductor package 20. The insulating film 50 has a first (or one) surface 51 facing the semiconductor package 10, and a second (the other) surface 52 opposite to the first surface 51 and facing the semiconductor package 20. The semiconductor package 10 is located on the Z2-side of the insulating film 50, and the semiconductor package 20 is located on the Z1-side of the insulating film 50. A material used for the insulating film 50 is polyimide, for example. The first surface 51 is an example of a ninth surface, and the second surface 52 is an example of a tenth surface.

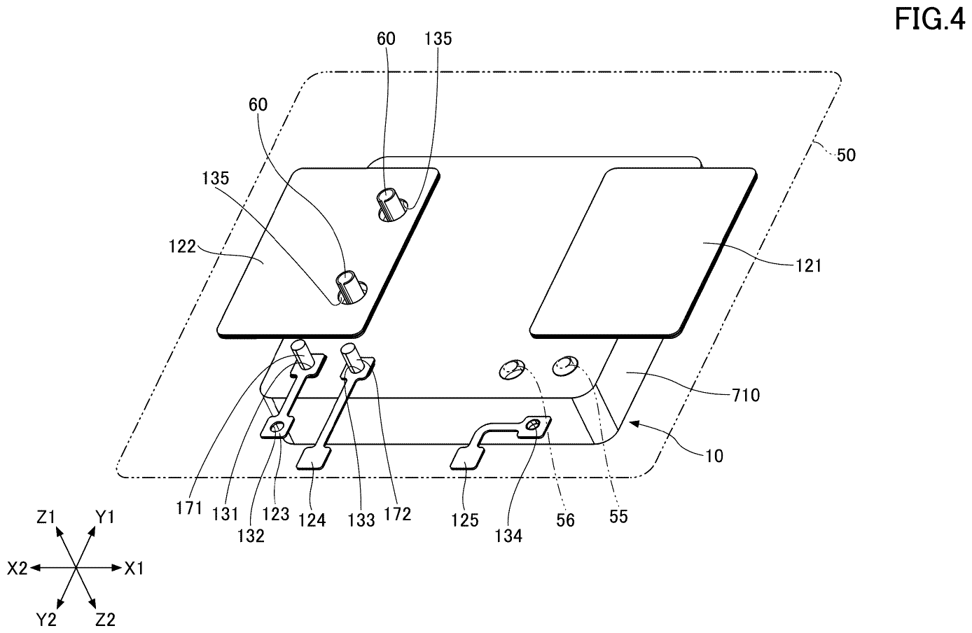

As illustrated in FIG. 4, FIG. 11, and FIG. 12, conductive layers 121, 122, 123, 124, and 125 are provided on the first surface 51 of the insulating film 50. The conductive layer 121 is located on the X1-side of the conductive layer 122. For example, the conductive layers 123 and 124 are located on the Y2-side of the conductive layer 122, and the conductive layer 125 is located on the Y2-side of the conductive layer 121. The conductive layer 124 is located on the X1-side of the conductive layer 123, and the conductive layer 125 is located on the X1-side of the conductive layer 124. The conductive layers 121 and 122 have a planar shape that is a rectangular shape, for example. The conductive layers 123 and 124 extend along the Y-axis, and have a longitudinal direction parallel to the Y-axis and a transverse direction parallel to the X-axis. For example, the conductive layer 125 has a planar shape that is an approximate L-shape including a portion extending in the X-axis direction toward the X1-side from a corner of the L-shape, and a portion extending in the Y-axis direction toward the Y2-side from the corner of the L-shape.

As illustrated in FIG. 3, FIG. 11, and FIG. 12, conductive layers 221, 222, 223, 224, and 225 are provided on the second surface 52 of the insulating film 50. The conductive layer 221 is located on the X2-side of the conductive layer 222. For example, the conductive layers 223 and 224 are located on the Y2-side of the conductive layer 222, and the conductive layer 225 is located on the Y2-side of the conductive layer 221. The conductive layer 224 is located on the X2-side of the conductive layer 223, and the conductive layer 225 is located on the X2-side of the conductive layer 224. The conductive layers 221 and 222 have a planar shape that is a rectangular shape, for example. The conductive layers 223 and 224 extend along the Y-axis, and have a longitudinal direction parallel to the Y-axis and a transverse direction parallel to the X-axis. For example, the conductive layer 225 has a planar shape that is an approximate L-shape including a portion extending in the X-axis direction toward the X2-side from a corner of the L-shape, and a portion extending in the Y-axis direction toward the Y2-side from the corner of the L-shape.

In the plan view, the conductive layer 121 and the conductive layer 222 overlap, and the conductive layer 122 and the conductive layer 221 overlap. Moreover, in the plan view, an end portion of the conductive layer 123 on the Y2-side and an end portion of the conductive layer 225 on the X2-side overlap, an end portion of the conductive layer 124 on the Y2-side and an end portion of the conductive layer 225 on the Y2-side overlap, an end portion of the conductive layer 223 on the Y2-side and an end portion of the conductive layer 125 on the X1-side overlap, and an end portion of the conductive layer 224 on the Y2-side and an end portion of the conductive layer 125 on the Y2-side overlap. The conductive layer 121 is an example of a first conductive layer, the conductive layer 222 is an example of a second conductive layer, and the conductive layers 122 and 221 are examples of a third conductive layer.

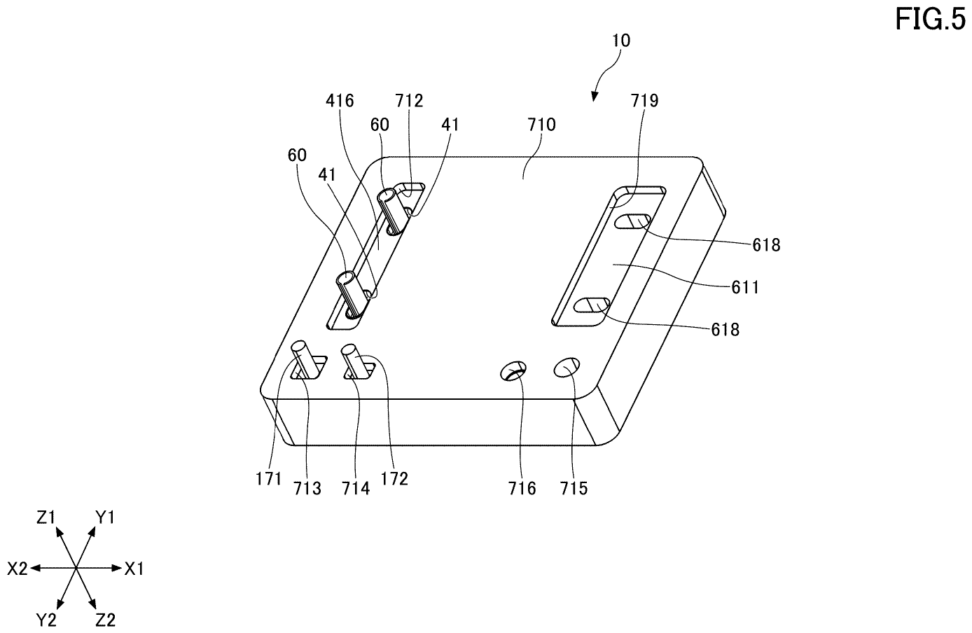

As illustrated in FIG. 5 through FIG. 7, FIG. 11, and FIG. 13, the semiconductor package 10 includes two semiconductor devices 100, a flexible wiring board 410, two shims 510, a lead terminal 611, a lead terminal 612, a conductive pin 171, a conductive pin 172, and a mold 710.

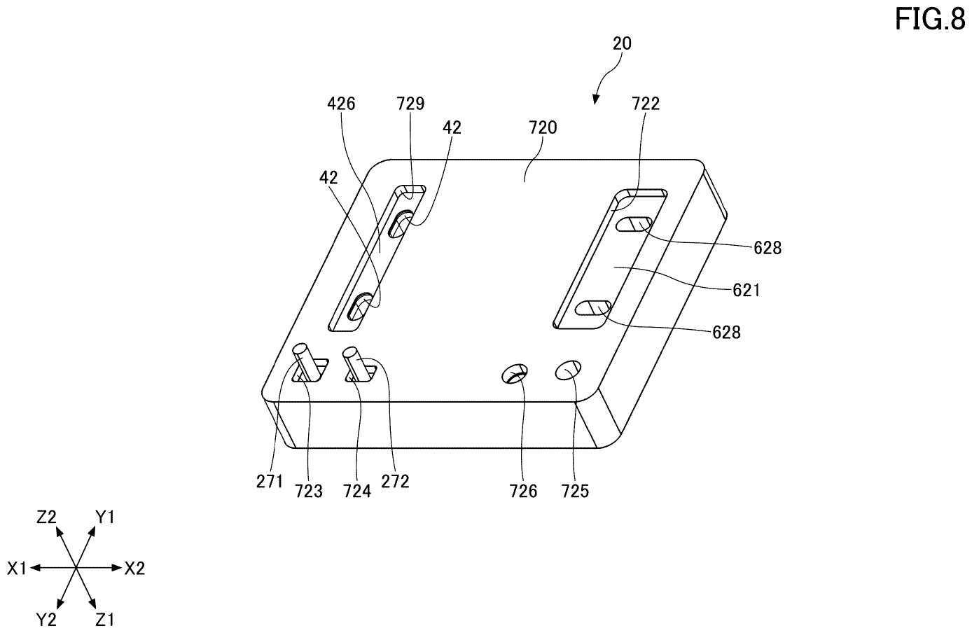

As illustrated in FIG. 8 through FIG. 11 and FIG. 14, the semiconductor package 20 includes two semiconductor devices 200, a flexible wiring board 420, two shims 520, a lead terminal 621, a lead terminal 622, a conductive pin 271, a conductive pin 272, and a mold 720.

The semiconductor devices 100 and 200 are formed using silicon (Si) or silicon carbide (SiC), for example. The semiconductor devices 100 and 200 may be formed using gallium nitride (GaN) or gallium arsenide (GaAs). For example, the semiconductor devices 100 and 200 may be insulated gate bipolar transistors (IGBTs) or metal-oxide-semiconductor field-effect transistors (MOSFETs). The semiconductor devices 100 and 200 have a planar shape that is a rectangular shape, for example. A thickness of each of the semiconductor devices 100 and 200 is in a range of approximately 50 μm to approximately 500 μm, for example.

As illustrated in FIG. 11, the semiconductor device 100 has a first surface 101 and a second surface 102 opposite to the first surface 101. The semiconductor device 100 includes a main body 110, an electrode 111, an electrode 112, and an electrode 113. The electrode 111 and the electrode 113 are provided on the first surface 101, and the electrode 112 is provided on the second surface 102. For example, the electrode 111, the electrode 112, and the electrode 113 are a source electrode, a drain electrode, and a gate electrode, respectively. The semiconductor device 100 is an example of a first semiconductor device, the first surface 101 is an example of a first surface, and the second surface 102 is an example of a second surface. The electrode 111 is an example of a first electrode, the electrode 112 is an example of a second electrode, and the electrode 113 is an example of a fifth electrode.

As illustrated in FIG. 11, the semiconductor device 200 has a first surface 201 and a second surface 202 opposite to the first surface 201. The semiconductor device 200 includes a main body 210, an electrode 211, an electrode 212, and an electrode 213. The electrode 211 and the electrode 213 are provided on the first surface 201, and the electrode 212 is provided on the second surface 202. For example, the electrode 211, the electrode 212, and the electrode 213 are a source electrode, a drain electrode, and a gate electrode, respectively. The semiconductor device 200 is an example of a second semiconductor device, the first surface 201 is an example of a third surface, and the second surface 202 is an example of a fourth surface. The electrode 211 is an example of a third electrode, the electrode 212 is an example of a fourth electrode, and the electrode 213 is an example of a sixth electrode.

A material used for the electrode 111, the electrode 112, the electrode 113, the electrode 211, the electrode 212, and the electrode 213 (hereinafter, these electrodes may be collectively referred to as “electrodes”) may be a metal, such as aluminum (Al), copper (Cu) or the like, or an alloy including at least one metal selected from these metals, for example. A surface treatment layer may be formed on a surface of the electrodes, as necessary. Examples of the surface treatment layer include a gold (Au) layer, a nickel (Ni) layer/Au layer (a metal layer in which a Ni layer and a Au layer are stacked in this order), a Ni layer/palladium (Pd) layer/Au layer (a metal layer in which a Ni layer, a Pd layer, and an Au layer are stacked in this order), or the like. A metal layer (electroless plating metal layer) formed by an electroless plating method, for example, can be used for the Au layer, the Ni layer, and the Pd layer. Further, the Au layer is a metal layer made of Au or an Au alloy, the Ni layer is a metal layer made of Ni or an Ni alloy, and the Pd layer is a metal layer made of Pd or a Pd alloy.

The shims 510 and 520 are metal plates, such as Cu plates or the like, for example. Thicknesses of the shims 510 and 520 are approximately the same as the thicknesses of the semiconductor devices 100 and 200.

The flexible wiring board 410 includes an insulating base material 411, an insulating adhesive layer 412, and an interconnect layer 415. The insulating base material 411 has a first surface 413 and a second surface 414 opposite to the first surface 413. The insulating adhesive layer 412 is provided on the first surface 413, and the interconnect layer 415 is provided on the second surface 414. The insulating adhesive layer 412 may be provided on the entire first surface 413. The interconnect layer 415 is stacked on the second surface 414. The insulating base material 411 is an example of a first insulating base material. The first surface 413 is an example of a fifth surface, and the second surface 414 is an example of a sixth surface.

The insulating base material 411 is a resin film, for example. Examples of a resin material used for the resin film include an insulating resin, such as a polyimide-based resin, a polyethylene-based resin, an epoxy-based resin, or the like. The insulating base material 411 has flexibility, for example. The flexibility of the material refers to a property that allows the material to be bent or deflected. A planar shape of the insulating base material 411 is a rectangular shape, for example. A thickness of the insulating base material 411 is approximately 50 μm to approximately 100 μm, for example.

The semiconductor device 100 and the shim 510 are bonded to the first surface 413 of the insulating base material 411 by the insulating adhesive layer 412. The first surface 101 of the semiconductor device 100 faces the first surface 413 of the insulating base material 411. A through hole 418 reaching the electrode 111 and a through hole (not illustrated) reaching the electrode 113 are formed in the insulating base material 411 and the insulating adhesive layer 412. A plurality of through holes 418 may be formed. The shim 510 is located at a position on the X2-side of the semiconductor device 100.

A material used for the insulating adhesive layer 412 may be an epoxy-based adhesive, a polyimide-based adhesive, a silicone-based adhesive, or the like, for example. A thickness of the insulating adhesive layer 412 is approximately 20 μm to approximately 40 μm, for example.

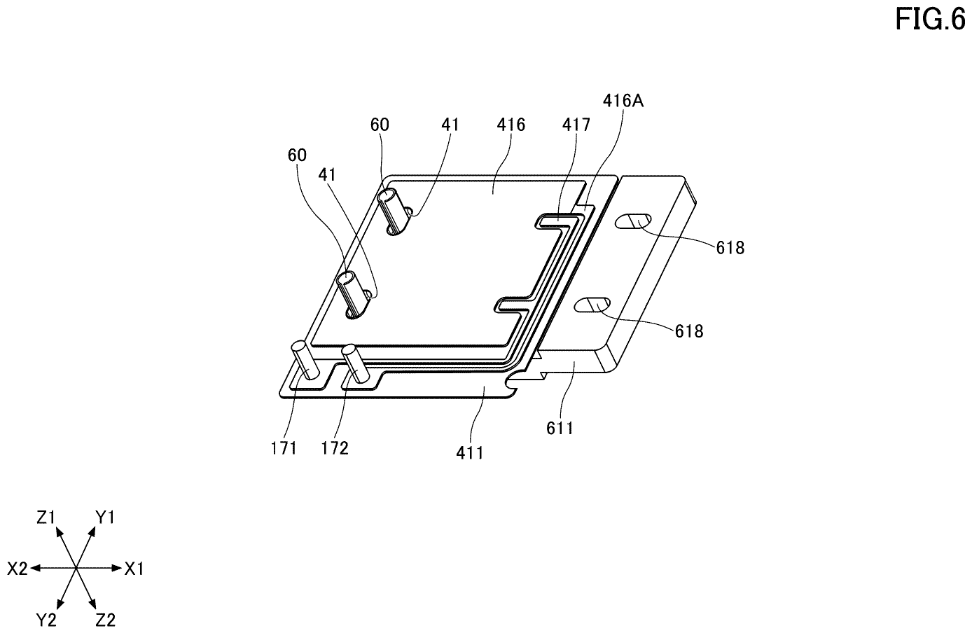

As illustrated in FIG. 6 and FIG. 11, the interconnect layer 415 includes an interconnect 416 connected to the electrode 111 via the through hole 418, an interconnect 417 connected to the electrode 113 via the through hole (not illustrated), and an interconnect 416A connected to the interconnect 416. The interconnect 416 is an example of a first conductive member, and the interconnect 417 is an example of a seventh conductive member.

The interconnect 416 includes a via interconnect filling an inside of the through hole 418, and an interconnect pattern formed on the second surface 414 of the insulating base material 411. The interconnect 417 includes a via interconnect filling an inside of a through hole (not illustrated), and an interconnect pattern formed on the second surface 414 of the insulating base material 411. The interconnect 416A includes an interconnect pattern formed on the second surface 414 of the insulating base material 411.

The lead terminal 611 is bonded to the electrode 112 of the semiconductor device 100 by the conductive adhesive layer 613. The lead terminal 612 is bonded to the shim 510 by the conductive adhesive layer 614. In the plan view, the lead terminal 611 extends from the semiconductor device 100 toward the X1-side. The lead terminals 611 and 612 are formed of a lead frame made of Cu, for example. The conductive adhesive layers 613 and 614 are solder layers or sintered metal layers, for example. The conductive adhesive layers 613 and 614 may be made of a conductive paste. The lead terminal 611 is an example of a second conductive member. A stack 616 of the shim 510, the conductive adhesive layer 614, and the lead terminal 612 is an example of a sixth conductive member.

As illustrated in FIG. 6, the conductive pin 171 is bonded to the interconnect 417 by a conductive adhesive layer (not illustrated), and the conductive pin 172 is bonded to the interconnect 416A by a conductive adhesive layer (not illustrated). The conductive pin 171 is electrically connected to the interconnect 417, and the conductive pin 172 is electrically connected to the interconnect 416A. The conductive pin 171 extends from the interconnect 417 toward the Z1-side, and the conductive pin 172 extends from the interconnect 416A toward the Z1-side. The conductive pin 171 is an example of a ninth conductive member.

As illustrated in FIG. 11, the mold 710 encapsulates the semiconductor device 100, the flexible wiring board 410, the shim 510, the lead terminal 611, and the lead terminal 612. The mold 710 has a first surface 717 and a second surface 718 opposite to the first surface 717. An end portion of the conductive layer 121 on the X1-side extends from the mold 710, and an end portion of the conductive layer 122 on the X2-side extends from the mold 710. The first surface 717 of the mold 710 faces the insulating film 50. An opening 711 reaching a lower surface (a surface on the Z2-side) of the lead terminal 611 is formed in the second surface 718 of the mold 710. The mold 710 is an example of a first encapsulating member.

The flexible wiring board 420 includes an insulating base material 421, an insulating adhesive layer 422, and an interconnect layer 425. The insulating base material 421 has a first surface 423 and a second surface 424 opposite to the first surface 423. The insulating adhesive layer 422 is provided on the first surface 423, and the interconnect layer 425 is provided on the second surface 424. The insulating adhesive layer 422 may be provided on the entire first surface 423. The interconnect layer 425 is stacked on the second surface 424. The insulating base material 421 is an example of a second insulating base material. The first surface 423 is an example of a seventh surface, and the second surface 424 is an example of an eighth surface.

The semiconductor device 200 and the shim 520 are bonded to the first surface 423 of the insulating base material 421 by the insulating adhesive layer 422. The first surface 201 of the semiconductor device 200 faces the first surface 423 of the insulating base material 421. A through hole 428 reaching the electrode 211 and a through hole (not illustrated) reaching the electrode 213 are formed in the insulating base material 421 and the insulating adhesive layer 422. A plurality of through holes 428 may be formed. The shim 520 is located at a position on the X1-side of the semiconductor device 200.

A material used for and a thickness of the insulating base material 421 are the same as the material used for and the thickness of the insulating base material 411, for example. A material used for and a thickness of the insulating adhesive layer 422 are the same as the material used for and the thickness of the insulating adhesive layer 412, for example.

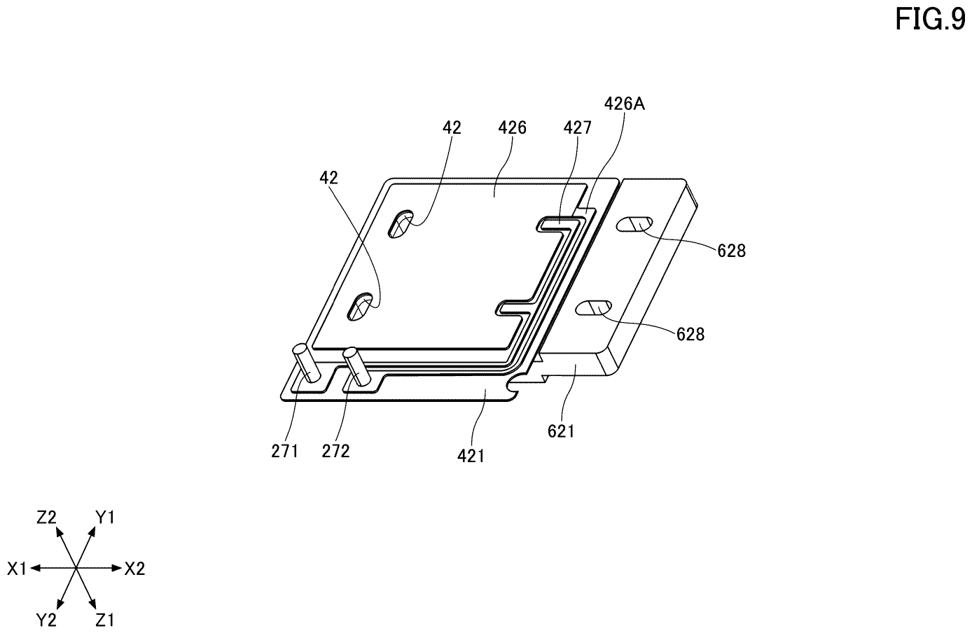

As illustrated in FIG. 9 and FIG. 11, the interconnect layer 425 includes an interconnect 426 connected to the electrode 211 via the through hole 428, an interconnect 427 connected to the electrode 213 via the through holes (not illustrated), and an interconnect 426A connected to the interconnect 426. The interconnect 426 is an example of a third conductive member, and the interconnect 427 is an example of an eighth conductive member.

The interconnect 426 includes a via interconnect filling an inside of the through hole 428, and an interconnect pattern formed on the second surface 424 of the insulating base material 421. The interconnect 427 includes a via interconnect filling an inside of a through hole (not illustrated), and an interconnect pattern formed on the second surface 424 of the insulating base material 421. The interconnect 426A includes an interconnect pattern formed on the second surface 424 of the insulating base material 421.

The lead terminal 621 is bonded to the electrode 212 of the semiconductor device 200 by a conductive adhesive layer 623. The lead terminal 622 is bonded to the shim 520 by a conductive adhesive layer 624. In the plan view, the lead terminal 621 extends from the semiconductor device 100 toward the X2-side. The lead terminals 621 and 622 are formed of a lead frame made of Cu, for example. The conductive adhesive layers 623 and 624 are solder layers or sintered metal layers, for example. The conductive adhesive layers 623 and 624 may be made of a conductive paste. The lead terminal 621 is an example of a fourth conductive member.

As illustrated in FIG. 9, the conductive pin 271 is bonded to the interconnect 427 by a conductive adhesive layer (not illustrated), and the conductive pin 272 is bonded to the interconnect 426A by a conductive adhesive layer (not illustrated). The conductive pin 271 is electrically connected to the interconnect 427, and the conductive pin 272 is electrically connected to the interconnect 426A. The conductive pin 271 extends from the interconnect 427 toward the Z2-side, and the conductive pin 272 extends from the interconnect 426A toward the Z2-side. The conductive pin 271 is an example of a tenth conductive member.

As illustrated in FIG. 11, the mold 720 encapsulates the semiconductor device 200, the flexible wiring board 420, the shim 520, the lead terminal 621, and the lead terminal 622. The mold 720 has a first surface 727 and a second surface 728 opposite to the first surface 727. An end portion of the conductive layer 221 on the X2-side extends from the mold 720, and an end portion of the conductive layer 222 on the X1-side extends from the mold 720. The first surface 727 of the mold 720 faces the insulating film 50. An opening 721 reaching an upper surface (a surface on the Z1-side) of the lead terminal 621 is formed in the second surface 728 of the mold 720. The mold 720 is an example of a second encapsulating member.

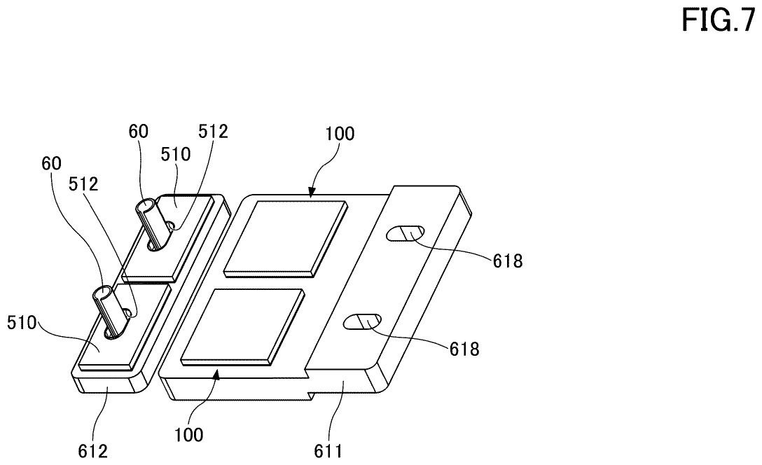

As illustrated in FIG. 11, the stack 616 has a surface 511 facing the lead terminal 621 and in contact with the insulating adhesive layer 412. A hole 512 is formed in the surface 511. A plurality of holes 512, such as two holes, for example, may be formed in the surface 511. For example, the hole 512 penetrates the shim 510 and the conductive adhesive layer 614, and reaches a point midway through a thickness direction of the lead terminal 612. As illustrated in FIG. 7, the hole 512 extends along the Y-axis, for example, and has a longitudinal direction parallel to the Y-axis and a transverse direction parallel to the X-axis. A through hole 41 overlapping the hole 512 is formed in the flexible wiring board 410. The number of through holes 41 is the same as the number of holes 512. For example, as illustrated in FIG. 6, a planar shape and size of the through hole 41 are the same as the planar shape and size of the hole 512. In addition, as illustrated in FIG. 5, an opening 712 reaching the interconnect 416 is formed in the first surface 717 of the mold 710. The opening 712 extends along the Y-axis, for example, and has a longitudinal direction parallel to the Y-axis and a transverse direction parallel to the X-axis. For example, all of the through holes 41 and the holes 512 are located inside the opening 712 in the plan view. The surface 511 is an example of an eleventh surface, the hole 512 is an example of a first hole, and the Y-axis is an example of a first axis.

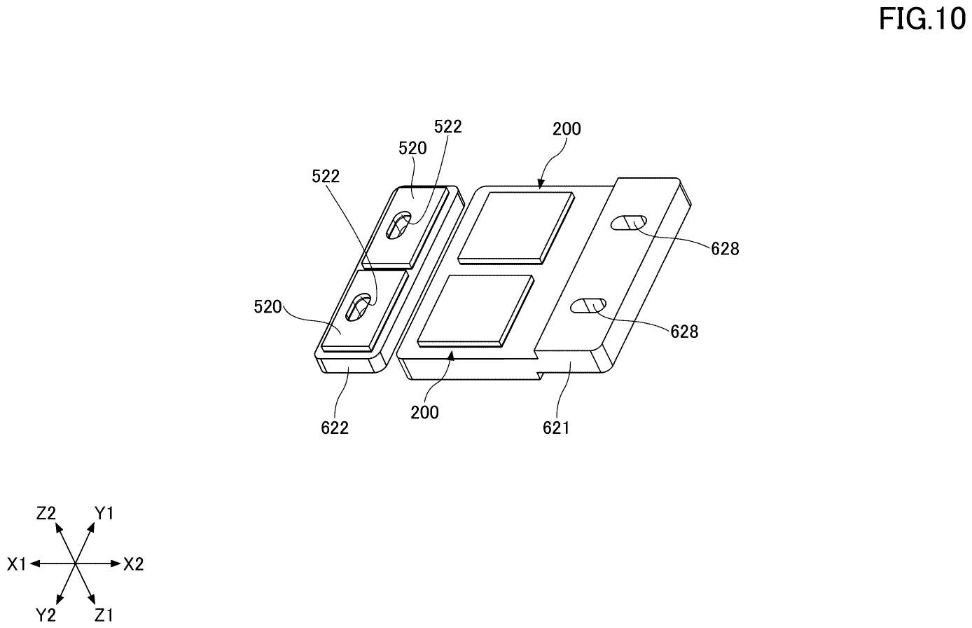

As illustrated in FIG. 11, the lead terminal 621 has a surface 627 facing the stack 616. A hole 628 is formed at a position separated from the flexible wiring board 420 in the plan view of the surface 627. The number of holes 628 that are formed is the same as the number of holes 512 that are formed. The hole 628 reaches a point midway through a thickness direction of the lead terminal 621. As illustrated in FIG. 10, the hole 628 extends along the X-axis, for example, and has a longitudinal direction parallel to the X-axis and a transverse direction parallel to the Y-axis. The hole 628 intersects the hole 512 in the plan view. For example, the hole 512 and the hole 628 are perpendicular to each other in the plan view. Further, as illustrated in FIG. 8, an opening 722 reaching the lead terminal 621 is formed in the first surface 727 of the mold 720. The opening 722 extends along the Y-axis, for example, and has a longitudinal direction parallel to the Y-axis and a transverse direction parallel to the X-axis. For example, all of the holes 628 are located inside the opening 722 in the plan view. The surface 627 is an example of a twelfth surface, the hole 628 is an example of a second hole, and the X-axis is an example of a second axis.

As illustrated in FIG. 5 and FIG. 12, an opening 713 reaching the interconnect 417 and an opening 714 reaching the interconnect 416A are formed in the first surface 717 of the mold 710. In addition, the mold 710 is provided with through holes 715 and 716 penetrating the mold 710 along the Z-axis. In the plan view, the through hole 715 overlaps the interconnect 427, and the through hole 716 overlaps the interconnect 426A.

As illustrated in FIG. 8 and FIG. 12, an opening 723 reaching the interconnect 427 and an opening 724 reaching the interconnect 426A are formed in the first surface 727 of the mold 720. Further, the mold 720 is provided with through holes 725 and 726 penetrating the mold 720 along the Z-axis. In the plan view, the through hole 725 overlaps the interconnect 417, and the through hole 726 overlaps the interconnect 416A. In the plan view, the opening 723 overlaps the through hole 715, the opening 724 overlaps the through hole 716, the through hole 725 overlaps the opening 713, and the through hole 726 overlaps the opening 714.

As illustrated in FIG. 3, FIG. 4, FIG. 11, and FIG. 12, the insulating film 50 is formed with through holes 53, 54, 55, 56, and 57 penetrating the insulating film 50 along the Z-axis. In the plan view, the through hole 53 overlaps the interconnect 417, the through hole 54 overlaps the interconnect 416A, the through hole 55 overlaps the interconnect 427, and the through hole 56 overlaps the interconnect 426A. In the plan view, the through hole 57 overlaps the hole 512, the through hole 41, the opening 712, the opening 722, and the hole 628.

As illustrated in FIG. 4 and FIG. 12, a through hole 131 penetrating the conductive layer 123 is formed at an end portion of the conductive layer 123 on the Y1-side, and a through hole 132 penetrating the conductive layer 123 is formed at an end portion of the conductive layer 123 on the Y2-side. A through hole 133 penetrating the conductive layer 124 is formed at an end portion of the conductive layer 124 on the Y1-side. A through hole 134 penetrating the conductive layer 125 is formed at an end portion of the conductive layer 125 on the X1-side. The conductive pin 171 penetrates the conductive layer 123 and the insulating film 50 through the through holes 131 and 53, and extends to an inside of the through hole 725. The conductive pin 171 is in contact with the conductive layer 123 and is electrically connected to the conductive layer 123. The conductive pin 172 penetrates the conductive layer 124 and the insulating film 50 through the through holes 133 and 54, and extends to an inside of the through hole 726. The conductive pin 172 is in contact with the conductive layer 124 and is electrically connected to the conductive layer 124. The conductive layer 123 is electrically connected to the interconnect 417 via the conductive pin 171, and the conductive layer 124 is electrically connected to the interconnect 416A via the conductive pin 172. The conductive layer 123 is an example of a fourth conductive layer.

As illustrated in FIG. 3 and FIG. 12, a through hole 231 penetrating the conductive layer 223 is formed at an end portion of the conductive layer 223 on the Y1-side, and a through hole 232 penetrating the conductive layer 223 is formed at an end portion of the conductive layer 223 on the Y2-side. A through hole 233 penetrating the conductive layer 224 is formed at an end portion of the conductive layer 224 on the Y1-side. A through hole 234 penetrating the conductive layer 225 is formed at an end portion of the conductive layer 225 on the X2-side. The conductive pin 271 penetrates the conductive layer 223 and the insulating film 50 through the through holes 231 and 55, and extends to an inside of the through hole 715. The conductive pin 271 is in contact with the conductive layer 223 and is electrically connected to the conductive layer 223. The conductive pin 272 penetrates the conductive layer 224 and the insulating film 50 through the through holes 233 and 56, and extends to an inside of the through hole 716. The conductive pin 272 is in contact with the conductive layer 224 and is electrically connected to the conductive layer 224. The conductive layer 223 is electrically connected to the interconnect 427 via the conductive pin 271, and the conductive layer 224 is electrically connected to the interconnect 426A via the conductive pin 272. The conductive layer 223 is an example of a fifth conductive layer.

As illustrated in FIG. 3 and FIG. 4, the through hole 132 in the conductive layer 123 and the through hole 234 in the conductive layer 225 overlap, and the through hole 232 in the conductive layer 223 and the through hole 134 in the conductive layer 125 overlap.

As illustrated in FIG. 4, a through hole 135 penetrating the conductive layer 122 is formed in the conductive layer 122. As illustrated in FIG. 3, a through hole 235 penetrating the conductive layer 221 is formed in the conductive layer 221. The through holes 135 and 235 overlap the hole 512, the through hole 41, the opening 712, the through hole 57, the opening 722, and the hole 628 in the plan view.

A material used for the conductive pins 60 may be a metal, such as aluminum (Al), copper (Cu) or the like, or an alloy including at least one metal selected from these metals, for example. The conductive pin 60 electrically connects the stack 616 and the lead terminal 621. The conductive pin 60 may be in contact with the stack 616 and the lead terminal 621. The conductive pin 60 penetrates the through hole 41, the opening 712, the through hole 135, the through hole 57, the through hole 235, and the opening 722, and one end portion (the end portion on the Z2-side) of the conductive pin 60 is inserted into the hole 512 of the stack 616, while the other end portion (the end portion on the Z1-side) of the conductive pin 60 is inserted into the hole 628 of the lead terminal 621. The conductive pin 60 may be fitted into the holes 512 and 628, and may be in contact with an inner wall surface of the hole 512 and an inner wall surface of the hole 628.

The conductive pins 60 have a substantially cylindrical shape with a slit formed along a longitudinal direction thereof, for example. In this case, a cross section of each conductive pin 60 perpendicular to the longitudinal direction have an arc shape. The conductive pins 60 may have a cylindrical shape or a columnar shape. The conductive pins 60 may have a polygonal cylindrical shape or a polygonal prism shape. When the conductive pins 60 have the cylindrical shape which may be hollow, the conductive pins 60 are more easily deformed elastically compared the conductive pins 60 having the columnar shape, and the cylindrical conductive pins 60 can more easily make contact with the stack 616 and the lead terminal 621. In a case where the conductive pins 60 have the cylindrical shape with the slit is formed along the longitudinal direction thereof, the conductive pins 60 are even more easily deformed elastically, and can even more easily make contact with the stack 616 and the lead terminal 621. The easier the conductive pins 60 can make contact with the stack 616 and the lead terminal 621, the higher a reliability of the connection becomes. The conductive pins 60 are examples of a fifth conductive member.

The conductive bonding material 61 is provided inside the hole 512, the through hole 41, the opening 712, the through hole 135, the through hole 57, the through hole 235, the opening 722, and the hole 628. The conductive bonding material 61 is in contact with the conductive pins 60, the stack 616, the interconnect 416, the conductive layer 122, the conductive layer 221, and the lead terminal 621, and electrically connects the conductive pins 60, the stack 616, the interconnect 416, the conductive layer 122, the conductive layer 221, and the lead terminal 621 to one another. The conductive bonding material 61 is a brazing material, a solder material, or a sintered metal material, for example.

As illustrated in FIG. 11, the stack 626 has a surface 521 facing the lead terminal 622 and in contact with the insulating adhesive layer 422. The surface 521 may have a hole 522 formed therein. A plurality of holes 522, such as two holes, for example, may be formed in the surface 521. For example, the hole 522 penetrates the shim 520 and the conductive adhesive layer 624, and reaches a point midway through a thickness direction of the lead terminal 622. As illustrated in FIG. 10, the hole 522 extends along the Y-axis, for example, and has a longitudinal direction parallel to the Y-axis and a transverse direction parallel to the X-axis. A through hole 42 overlapping the hole 522 may be formed in the flexible wiring board 420. The number of through holes 42 may be the same as the number of holes 522. For example, as illustrated in FIG. 9, the planar shape and size of the through hole 42 are the same as the planar shape and size of the hole 522. In addition, as illustrated in FIG. 8, an opening 729 reaching the interconnect 426 is formed in the first surface 727 of the mold 720. The opening 729 extends along the Y-axis, for example, and has a longitudinal direction parallel to the Y-axis and a transverse direction parallel to the X-axis. For example, all of the through holes 42 and the holes 522 are located inside the opening 729 in the plan view.

As illustrated in FIG. 11, the lead terminal 611 has a surface 617 facing the stack 626. A hole 618 may be formed in the surface 617 at a position separated from the flexible wiring board 410 in the plan view. The number of holes 618 may be the same as the number of holes 522. The hole 618 reaches a point midway through a thickness direction of the lead terminal 611. As illustrated in FIG. 6, the hole 618 extends along the X-axis, for example, and has a longitudinal direction parallel to the X-axis and a transverse direction parallel to the Y-axis. The hole 618 intersects the hole 522 in the plan view. For example, the hole 522 and the hole 618 are perpendicular to each other in the plan view. As illustrated in FIG. 5, an opening 719 reaching the lead terminal 611 is formed in the first surface 717 of the mold 710. The opening 719 extends along the Y-axis, for example, and has a longitudinal direction parallel to the Y-axis and a transverse direction parallel to the X-axis. For example, all of the holes 618 are located inside the opening 719 in the plan view.

The conductive bonding material 62 is provided inside the hole 618 and the opening 719. The conductive bonding material 62 is in contact with the lead terminal 611 and the conductive layer 121, and electrically connects the lead terminal 611 and the conductive layer 121. The conductive bonding material 63 is provided inside the hole 522, the through hole 42, and the opening 729. The conductive bonding material 63 is in contact with the stack 626, the interconnect 426, and the conductive layer 222, and electrically connects the stack 626, the interconnect 426, and the conductive layer 222 to one another. The conductive bonding materials 62 and 63 are a brazing material, a solder material, or a sintered metal material, for example.

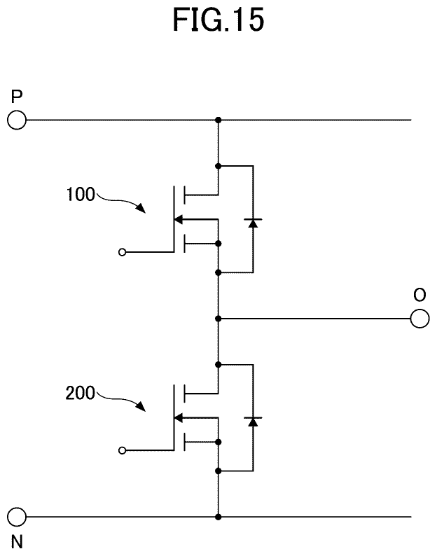

Next, a circuit configuration of the power module 1 according to the embodiment will be described. FIG. 15 is a circuit diagram illustrating a power module according to the embodiment. Although one semiconductor device 100 of the two semiconductor devices 100 and one semiconductor device 200 of the two semiconductor devices 200 are illustrated in FIG. 15 for the sake of convenience, the two semiconductor devices 100 are mutually connected in parallel, and the two semiconductor devices 200 are mutually connected in parallel. The power module 1 includes a half-bridge circuit illustrated in FIG. 15.

As illustrated in FIG. 15, the electrode 112 of the semiconductor device 100 is electrically connected to the conductive layer 121 as a P terminal via the lead terminal 611 and the conductive bonding material 62, and the electrode 211 of the semiconductor device 200 is electrically connected to the conductive layer 222 as an N terminal via the interconnect 426 and the conductive bonding material 63. In addition, the electrode 111 of the semiconductor device 100 is electrically connected to the conductive layers 122 and 221 as an O terminal via the interconnect 416 and the conductive bonding material 61, and the electrode 212 of the semiconductor device 200 is electrically connected to the conductive layers 122 and 221 as the O terminal via the lead terminal 621 and the conductive bonding material 61. Further, the lead terminal 612 and the lead terminal 621 are electrically connected via the conductive pin 60 and the conductive bonding material 61. The P terminal is an input terminal on the positive electrode side, the N terminal is an input terminal on the negative electrode side, and the O terminal is an output terminal. Accordingly, currents flow through the conductive layer 121 and the conductive layer 222 in opposite directions.

In addition, the electrode 113 of the semiconductor device 100 is electrically connected to the conductive layer 123 as a control terminal via the interconnect 417 and the conductive pin 171, and the electrode 213 of the semiconductor device 200 is electrically connected to the conductive layer 223 as a control terminal via the interconnect 427 and the conductive pin 271. Hence, a control signal from the conductive layer 123 is input to the electrode 113 of the semiconductor device 100, and a control signal from the conductive layer 223 is input to the electrode 213 of the semiconductor device 200.

The interconnect 416 is electrically connected to the conductive layer 124 as a sense source terminal via the interconnect 416A and the conductive pin 172, and the interconnect 426 is electrically connected to the conductive layer 224 as a sense source terminal via the interconnect 426A and the conductive pin 272. Further, in the plan view, the conductive layer 125 overlaps the conductive layers 223 and 224, and the conductive layer 225 overlaps the conductive layers 123 and 124. Accordingly, the conductive layer 125 functions as a shield layer with respect to the conductive layer 223, and the conductive layer 225 functions as a shield layer with respect to the conductive layer 123.

As described above, in the power module 1, the semiconductor device 100 is bonded to the first surface 413 of the insulating base material 411, the interconnect 416 is stacked on the second surface 414 of the insulating base material 411, the electrode 111 of the semiconductor device 100 is electrically connected to the interconnect 416, and the electrode 112 of the semiconductor device 100 is electrically connected to the lead terminal 611. In addition, the semiconductor device 200 is bonded to the first surface 423 of the insulating base material 421, the interconnect 426 is stacked on the second surface 424 of the insulating base material 421, the electrode 211 of the semiconductor device 200 is electrically connected to the interconnect 426, and the electrode 212 of the semiconductor device 200 is electrically connected to the lead terminal 621. The interconnect 416 and the lead terminal 621 are electrically connected via the conductive pin 60 and the conductive bonding material 61. The half-bridge circuit is configured in this manner. In addition, the conductive layer 121 electrically connected to the lead terminal 611 and the conductive layer 222 electrically connected to the interconnect 426 overlap in the plan view. Accordingly, a distance between the conductive layer 121 and the conductive layer 222 through which currents flow in opposite directions can be reduced, and the inductance can be significantly reduced. Moreover, the areas occupied by the conductive layers 121 and 222 can be reduced when compared to a configuration in which the lead terminals 611 and 622 are arranged side by side in the plan view. Hence, according to the present embodiment, a compact power module 1 can be obtained. In addition, because the influence on the size of the entire power module 1 is small even if widths of the lead terminals 611 and 622 in the Y1-Y2 direction are increased within ranges of widths of the molds 710 and 720 in the Y1-Y2 direction, interconnect resistances of the lead terminals 611 and 622 can be reduced by increasing the widths of the lead terminals 611 and 622 in the Y1-Y2 direction.

Further, because the X-axis is inclined from the Y-axis, and the Y-axis along which the hole 512 extends and the X-axis along which the hole 628 extends intersect each other in the plan view, even if a positional error occurs between the semiconductor package 10 and the semiconductor package 20 on the XY-plane, the conductive pins 60 are likely to be fitted into the holes 512 and 628.

Because the conductive pins 171, 172, 271, and 272 penetrate the conductive layer provided on the first surface 51 or the second surface 52 of the insulating film 50 and come into contact with the conductive layer, a conductive material, such as a through hole via or the like, does not need to be provided inside the through holes 53, 54, 55, and 56 of the insulating film 50. In addition, because the conductive pins 60 are electrically connected to the conductive layers 122 and 221 by the conductive bonding material 61 while penetrating the conductive layers 122 and 221 of the insulating film 50, a conductive material, such as a through hole via or the like, does not need to be provided inside the through hole 57. Accordingly, the cost can be reduced when compared to the case where a conductive material, such as a through hole via or the like, is provided.

The hole 618 may not be formed in the semiconductor package 10, and the hole 522 and the through hole 42 may not be formed in the semiconductor package 20. However, in the case where the hole 618 is formed in the semiconductor package 10, and the hole 522 and the through hole 42 are formed in the semiconductor package 20, the semiconductor packages 10 and 20 may have the same configuration, thereby making the semiconductor packages 10 and 20 suitable for mass production.

The openings 711 and 721 contribute to heat dissipation. For example, the power module 1 is mounted on a heat sink so that the opening 711 or 721 faces the heat sink, and a thermal interface material (TIM) is provided between the lead terminal 611 or 621 and the heat sink.

According to the disclosed technique, an inductance of a power module can be reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power module comprising:
a first semiconductor device having a first surface, a second surface opposite to the first surface, a first electrode provided on the first surface, and a second electrode provided on the second surface;
a second semiconductor device having a third surface, a fourth surface opposite to the third surface, a third electrode provided on the third surface, and a fourth electrode provided on the fourth surface;
a first insulating base material having a fifth surface bonded with the first semiconductor device, and a sixth surface opposite to the fifth surface;
a second insulating base material having a seventh surface bonded with the second semiconductor device, and an eighth surface opposite to the seventh surface;
a first conductive member penetrating the first insulating base material, electrically connected to the first electrode, and stacked on the sixth surface of the first insulating base material;
a second conductive member electrically connected to the second electrode;
a third conductive member penetrating the second insulating base material, electrically connected to the third electrode, and stacked on the eighth surface of the second insulating base material;
a fourth conductive member electrically connected to the fourth electrode;
a fifth conductive member electrically connecting the first conductive member and the fourth conductive member;
an insulating film having a ninth surface facing the first conductive member and the second conductive member, and a tenth surface facing the third conductive member and the fourth conductive member;
a first conductive layer provided on the ninth surface and electrically connected to the second conductive member; and
a second conductive layer provided on the tenth surface and electrically connected to the third conductive member,
wherein the first conductive layer and the second conductive layer overlap in a plan view.

2. The power module as claimed in claim 1, further comprising:
a sixth conductive member bonded to the fifth surface, wherein:
the first conductive member, the fourth conductive member, and the sixth conductive member overlap in the plan view,
the sixth conductive member has an eleventh surface facing the fourth conductive member and having a first hole,
the fourth conductive member has a twelfth surface facing the sixth conductive member and having a second hole, and
the fifth conductive member is inserted into the first hole and the second hole.

3. The power module as claimed in claim 2, wherein, in the plan view:
the first hole extends along a first axis, and
the second hole extends along a second axis inclined from the first axis.

4. The power module as claimed in claim 3, wherein the first axis and the second axis are perpendicular to each other.

5. The power module as claimed in claim 2, wherein the fifth conductive member is in contact with an inner wall surface of the first hole and an inner wall surface of the second hole.

6. The power module as claimed in claim 1, further comprising:
a third conductive layer provided on at least one of the ninth surface or the tenth surface, and electrically connected to the first conductive member, the fourth conductive member, and the fifth conductive member.

7. The power module as claimed in claim 6, further comprising:
a conductive bonding material that bonds the third conductive layer to the first conductive member, the fourth conductive member, and the fifth conductive member.

8. The power module as claimed in claim 1, wherein:
the first semiconductor device includes a fifth electrode provided on the first surface,
the second semiconductor device includes a sixth electrode provided on the third surface,
the power module further comprising:
a seventh conductive member penetrating the first insulating base material, electrically connected to the fifth electrode, and stacked on the sixth surface of the first insulating base material;
an eighth conductive member penetrating the second insulating base material, electrically connected to the sixth electrode, and stacked on the eighth surface of the second insulating base material;
a fourth conductive layer provided on the ninth surface and electrically connected to the seventh conductive member; and
a fifth conductive layer provided on the tenth surface and electrically connected to the eighth conductive member.

9. The power module as claimed in claim 8, further comprising:
a ninth conductive member in contact with the seventh conductive member and the fourth conductive layer; and
a tenth conductive member in contact with the eighth conductive member and the fifth conductive layer.

10. The power module as claimed in claim 1, wherein:
the insulating film is disposed between a first region and a second region,
the first region includes the first conductive member and the second conductive member, and
the second region includes the third conductive member and the fourth conductive member.
